(19) United States
(12) Patent Application Publication
(10) Pub. No.: US 2017/0215281 A1
(43) Pub. Date: Jul. 27, 2017

(54) DIELECTRIC VIAS IN MULTI-LAYER STRUCTURES

(71) Applicant: Avago Technologies General IP (Singapore) Pte. Ltd., Singapore (SG)

(72) Inventors: Martin Fritz, Munich (DE); Bernhard Gebauer, Tuntenhausen (DE)

(21) Appl. No.: 15/007,313

(22) Filed: Jan. 27, 2016

(51) Int. Cl. H05K 1/11; H01F 27/36; H01F 27/28

(52) U.S. Cl. CPC H05K 1/115; H01F 27/2804; H01F 27/362; H01F 2027/2809

(57) ABSTRACT

An apparatus includes electrically conductive structures disposed over, or partially in, a dielectric layer. The dielectric layer has a first relative permittivity (∈ᵣ₁). The apparatus also includes a dielectric via disposed in the dielectric layer. The dielectric via has a second relative permittivity (∈ᵣ₂) that is less than the first relative permittivity (∈ᵣ₁). The dielectric via is located in a region, or adjacent to the region, where a magnitude of an electric field between the first and second electrically conductive structures is comparatively large.

### BACKGROUND

In many communications devices (e.g., mobile phones), there are electronic modules (e.g., radio-frequency (RF) modules) disposed over a substrate. As the trend towards smaller electrical devices continues, there is a need to reduce the size of many components that comprise the device. For example, there is a need to reduce the height of the electronic module. Often, electronic modules comprise a substrate comprising a plurality of layers of dielectric material stacked over one another. One way to reduce package height is to reduce the thickness (height) of the substrate layers of the multilayer substrate. However, thinner substrate layers means a reduction in the distance between a first electrical conductor (e.g., an inductor) at one layer of the multilayer substrate and a second electrical conductor (e.g., a shielding layer) at another layer above or below the first electrical conductor.

Because the first and second electrical conductors are more closely spaced in the effort to reduce the overall substrate thickness, the parasitic capacitance associated with the first and second electrical conductors increases. The increase in parasitic capacitance results in a reduction in the characteristic impedance when an electrical conductor is a signal transmission line in the substrate, and a reduction of the inductance when an electrical conductor is a quasi lumped inductor (e.g., an buried inductor) in the substrate. Compensation for these degradations cannot be mitigated by decreasing the width of the electrical conductor (e.g., the line width of the inductor), because the line width is already selected to be comparatively small to attain a comparatively high inductance value. As such, the impedance transformation behavior of the electrical conductor, and consequently the performance of the overall module will be deleteriously impacted.

What is needed, therefore, is an apparatus that overcomes at least the noted shortcomings of known apparatuses described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals, refer to like elements.

FIGS. 1A and 1B are exploded cross-sectional and cross-sectional views, respectively, of an apparatus according to a representative embodiment.

FIGS. 2A and 2B are exploded cross-sectional and cross-sectional views, respectively, of an apparatus according to a representative embodiment.

FIGS. 3A and 3B are exploded cross-sectional and cross-sectional views, respectively, of an apparatus according to a representative embodiment.

FIGS. 4A and 4B are exploded cross-sectional and cross-sectional views, respectively, of an apparatus according to a representative embodiment.

FIG. 4C is a cross-sectional view of an apparatus according to a representative embodiment.

FIGS. 5A and 5B are exploded cross-sectional and cross-sectional views, respectively, of an apparatus according to a representative embodiment.

FIGS. 6A-6F are cross-sectional views of various layers of an apparatus according to a representative embodiment.

FIGS. 7A-7G are cross-sectional views of apparatuses according to a representative embodiment.

FIGS. 8A-8F are cross-sectional views of various layers of an apparatus according to a representative embodiment.

FIGS. 9A-9D are cross-sectional views of apparatuses according to a representative embodiment.

FIG. 10 is a cross-sectional view of an apparatuses according to a representative embodiment.

FIG. 11 is a cross-sectional view of an apparatuses according to a representative embodiment.

FIG. 12 is a cross-sectional view of an apparatuses according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

In accordance with a representative embodiment, an apparatus comprises a first electrically conductive structure at a first electrical potential, a second electrically conductive structure at a second electrical potential, and a dielectric layer disposed between the first electrically conductive structure and the second electrically conductive structure. The dielectric layer has a first relative permittivity (∈ᵣ₁). The apparatus also comprises a dielectric via disposed in the dielectric layer. The dielectric via has a second relative permittivity (∈ᵣ₂) that is less than the first relative permittivity (∈ᵣ₁). The dielectric via is located in a region, or adjacent to the region, where a magnitude of an electric field between the first and second electrically conductive structures is comparatively large.

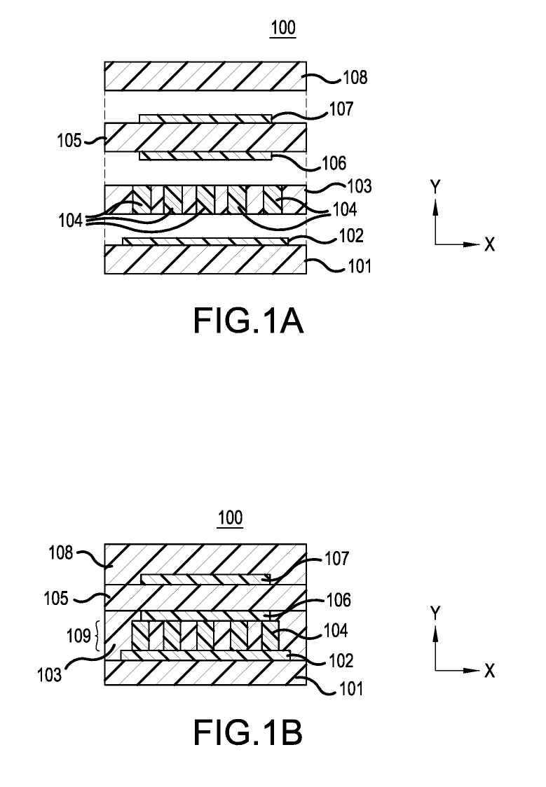

FIG. 1A depicts an exploded cross-sectional view of an apparatus 100 in accordance with a representative embodiment. Notably, the apparatus 100 may be a portion of a multi-layer structure that is a component of an electronic device or electronic module.

The apparatus 100 comprises a first dielectric layer 101, which has a first electrically conductive structure 102 disposed thereover. A second dielectric layer 103 is disposed over the first electrically conductive structure 102. The second dielectric layer 103 comprises a plurality of dielectric vias 104 disposed therein.

The apparatus 100 further comprises a third dielectric layer 105 disposed over the second dielectric layer 103. A second electrically conductive structure 106 is disposed over one side of the third dielectric layer 105, and a third electrically conductive structure 107 is disposed over an opposing side of the third dielectric layer 105.

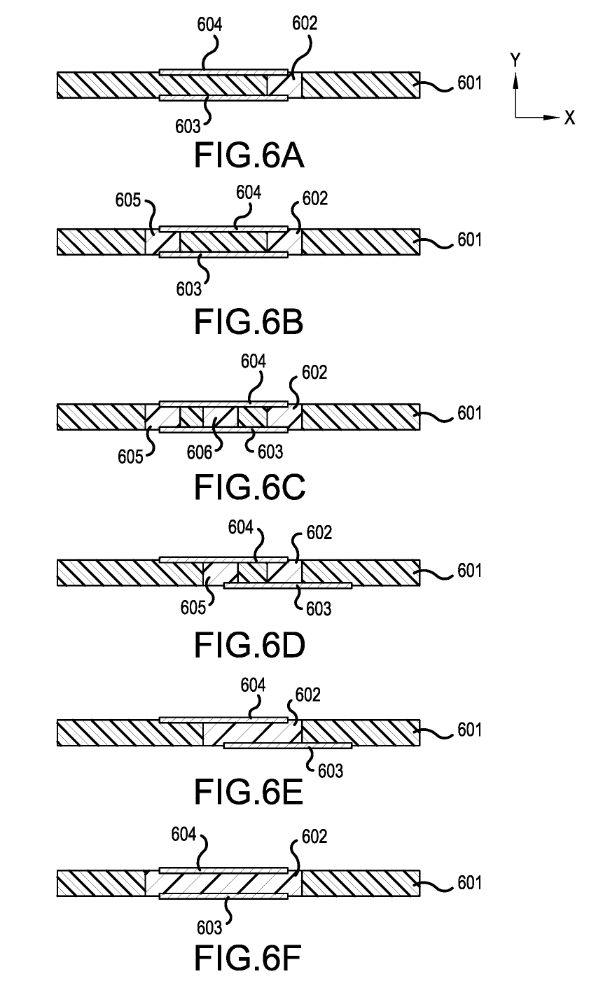

As depicted in FIG. 1A, first and second electrically conductive structures 102, 106 are disposed over first dielectric layer 101, and over third dielectric layer 106, respectively. It is noted that in general, the electrically conductive structures of the representative embodiments described herein may be disposed over respective dielectric layers, or may be disposed partially in respective dielectric layers (see, for example, FIG. 6A). Generally, the location of the electrically conductive structure (i.e., being disposed over a dielectric layer, or partially disposed in a dielectric layer) depends on the material used for the dielectric layer, and the process of forming the electrically conductive layer. Just by way of example, if so-called core or prepreg materials are used for the dielectric layers, the electrically conductive structures will be disposed over their respective dielectric layer. By contrast, if so-called core-less materials, or low temperature or high temperature co-fired ceramic are used for the dielectric layers, the electrically conductive structures will be disposed partially in their respective dielectric layer.

The apparatus 100 further comprises a fourth dielectric layer 108 disposed over the third dielectric layer 105. Notably, more or fewer dielectric layers, or more or fewer electrically conductive structures, or more of fewer dielectric vias (or combinations thereof) than those depicted in FIGS. 1A-1B are contemplated by the present teachings, as will become clearer as the present description continues. Moreover, there may be more or fewer different electrical potentials applied to the electrically conductive structures than explicitly described herein. Accordingly, the present teachings are not limited to the number of dielectric layers, or the number of electrically conductive structures, or the number of electrical potentials applied to the electrically conductive structures, or the number of dielectric vias depicted and described in connection with the representative embodiments herein.

Turning to FIG. 1B, the apparatus 100 is depicted in final form after assembly, where the various individual layers are not discerned.

The first˜fourth dielectric layers 101, 103,105, 108 comprise one or more of a variety of known materials, and are selected based on the particular application in the apparatus is implemented. These materials include, but are not limited to, glass-reinforced epoxy laminate materials (e.g. FR4), hydrocarbon ceramic laminate materials (e.g. Rogers 4003), polytetrafluorethylene (PTFE) composite laminates filled with random glass or ceramic (e.g. RT/Duroid), ceramic laminates (e.g. LTCC, HTCC), prepreg, teflon, aluminum oxide, ceramic or glass materials. Depending on the application, a wide range of ceramic materials are contemplated for the first˜fourth dielectric layers 101, 103,105, 108. Some examples include aluminum nitride, aluminum silicate, barium neodymium titanate, barium strontium titanate (BST), barium tantalate, barium titanate (BT), beryllia, boron nitride, calcium titanate, calcium magnesium titanate (CMT), magnesium aluminum silicate, lead zinc niobate (PZN), lithium niobate (LN), magnesium silicate, magnesium titanate, niobium oxide, porcelain, quartz, sapphire, strontium titanate, silica, tantalum oxide, zirconium oxide. Certain details of the materials and structures, and devices, of the apparatuses of the present teachings are described in one or more of the following commonly owned U.S. patents, which are specifically incorporated herein by reference: U.S. Pat. Nos. 8,946,904; 8,344,504; and 8,314,472.

The first˜fourth dielectric layers 101, 103,105, 108 have a thickness in the range of approximately several micrometers (μm) to approximately several millimeters (mm). In an illustrative example, the first˜fourth dielectric layers 101, 103,105, 108 have a minimum thickness of approximately 15 μm and a maximum thickness of several millimeters. The first˜fourth dielectric layers 101, 103,105, 108 have a first relative permittivity (∈ᵣ₁).

The first, second and third electrically conductive structures 102, 106, 107 are illustratively copper, or gold, or a multi-layer of copper and gold, although other electrically conductive materials, or material combinations within the purview of one of ordinary skill in the art are contemplated depending on the application or design parameters.

The first, second and third electrically conductive structures 102, 106, 107 may include a variety of metallization patterns used to effect various electrical components. In accordance with a representative embodiment, the first electrically conductive structure 102 is a shielding layer, which may be electrically connected to a reference ground; and the second and third electrically conductive layers 106, 107 are windings of an inductor. It is emphasized that the noted implementations of the first, second and third electrically conductive structures 102, 106, 107 are merely illustrative, and other implementations are contemplated. Just by way of example, and as described in connection with other representative embodiments herein, the first, second and third electrically conductive structures 102, 106, 107 and similar structures described herein may be inductors, transmission lines, or delay lines, as well as reference ground planes and shielding layers. In yet other embodiments described herein, the various electrically conductive structures may be impedance transformers.

The first, second and third electrically conductive structures 102, 106, 107 are fabricated using one of a variety of known methods (y-direction in the coordinate system shown). By way of example, the first, second and third electrically conductive structures 102, 106, 107 may be patterned by etching using known methods, and may be built up to a desired method by known methods as well. Illustratively, the first, second and third electrically conductive structures 102, 106, 107 have a thickness (y-direction) in the range of approximately 1.0 μm to approximately 50 μm, and a width (x-direction in the coordinate system shown) in the range of approximately several μm to approximately several millimeters. In an illustrative example, the first, second and third electrically conductive structures 102, 106, 107 have a width in the range of approximately 15 μm to approximately several millimeters.

The dielectric vias 104 provided in the second dielectric layer 103 include a material that has a second relative permittivity (∈ᵣ₂) that is lower than the first relative permittivity (∈ᵣ₁) of the first˜fourth dielectric layers 101, 103,105, 108.

The dielectric vias 104 have one or more of a selected geometry and size, selected to achieve a desired relative effective permittivity ∈_{r,eff} in a particular region of the apparatus 100, as described more fully below. The dielectric vias 104 may be formed by one or more of a variety of methods including mechanical drilling, laser-drilling, etching, and punching.

Moreover, the dielectric vias 104 may have a width (x-direction in the coordinate system shown) in the range of several micrometers to approximately several millimeters. In an illustrative example, the dielectric vias have a width of approximately 20 μm to approximately 750 μm. The dielectric vias 104 may have a thickness (y-direction in the coordinate system shown) that is substantially identical to the thickness of the particular dielectric layer in which they are disposed.

The dielectric vias 104 may include air or some other gas having a comparatively low dielectric constant, or may comprise other known materials having a comparatively low dielectric constant (sometimes referred to as low-k materials). The filling of the dielectric vias 104 with a material other than air may be done by a known method prior to assembly of the apparatus 100. As will be appreciated by one of ordinary skill in the art, the material provided in the dielectric vias 104 is selected based on various design parameters, and especially a desired relative effective permittivity ∈_{r,eff} as described below.

By providing the dielectric vias 104 in regions of the apparatus 100 where the magnitude of the electric field emanating between the second electrically conductive structure 106 and the first electrically conductive structure 102 is comparatively large, the parasitic capacitance between the second electrically conductive structure 106 and the first electrically conductive structure 102 is reduced compared to a structure that does not comprise the dielectric vias 104 of the representative embodiment. As noted above, unmitigated parasitic capacitance results in an undesired reduction in the characteristic impedance and/or reduction of inductance of an electronic component (e.g., transmission line or inductor).

Stated somewhat differently, in region 109 of FIG. 1B where the magnitude of the electric field is comparatively high, the dielectric vias 104, which have a low relative permittivity (∈ᵣ₂) compared to the relative permittivity of the second dielectric layer 103, provide a reduced relative effective permittivity ∈_{r,eff}, and therefore a reduction of the capacitive parasitics.

Generally, therefore, in apparatuses such as apparatus 100, dielectric vias 104 can be provided in the dielectric layers of the apparatus at locations where it is desired to reduce capacitive coupling effects. As described in accordance with representative embodiments below, such regions include, but are not limited to, regions between a shielding ground and inductor top and/or bottom winding, and/or laterally between inductor and shielding via bar. However, it can also be useful to implement these dielectric vias 104 between the metallization of the different windings of the coil, because the dielectric vias 104 will reduce the capacitance coupling between the windings, which will improve the inductive behavior of the coil. Furthermore the dielectric vias 104 can also be useful in signal transmission line structures, with the dielectric vias 104 disposed between a signal transmission signal line and corresponding electrical reference ground to adjust the characteristic line impedance. As will be appreciated by one of ordinary skill in the art, the ability to adjust the characteristic line impedance by reducing the relative effective permittivity ∈_{r,eff} in a particular region of a multi-layer apparatus such as apparatus 100, is especially useful when the relevant design parameters (e.g. line width) are already at the limit given by the design rule.

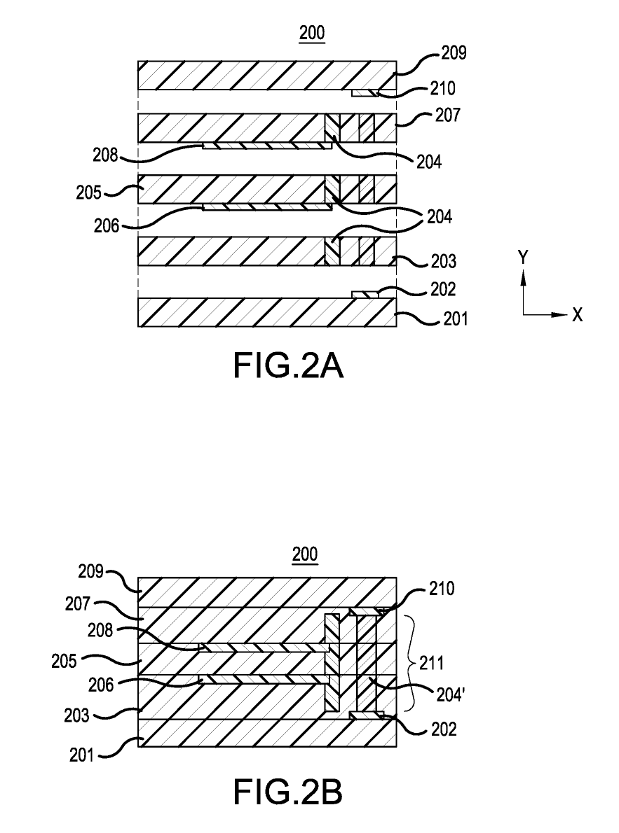

As noted previously, the present teachings contemplate locating the dielectric vias in a region where the magnitude of the electric field is comparatively high. FIGS. 2A-2B depict an apparatus 200 according to a representative embodiment where the dielectric vias are located near laterally shielded electrically conductive structures. Notably, many details of the various features described in connection with the representative embodiments of FIGS. 1A-1B are common to those of FIGS. 2A-2B. These details are not necessarily repeated in the description of FIGS. 2A-2B.

FIG. 2A depicts an exploded cross-sectional view of an apparatus 200 in accordance with a representative embodiment. Notably, the apparatus 200 may be a portion of a multi-layer structure that is a component of an electronic device or electronic module.

The apparatus 200 comprises a first dielectric layer 201, which has a first electrically conductive structure 202 disposed thereover. A second dielectric layer 203 is disposed over the first electrically conductive structure 202. The second dielectric layer 203 comprises one of a plurality of dielectric vias 204 disposed therein.

The apparatus 200 further comprises a third dielectric layer 205 disposed over the second dielectric layer 203. A second electrically conductive structure 206 is disposed over one side of the second dielectric layer 203. The third dielectric layer 205 also comprises one of the plurality of dielectric vias 204.

The apparatus 200 further comprises a fourth dielectric layer 207 disposed over the third dielectric layer 205. A third electrically conductive structure 208 is disposed over a side of the fourth dielectric layer 207, and between the third dielectric layer 205 and the fourth dielectric layer 207. The fourth dielectric layer 207 also comprises one of the plurality of dielectric vias 204.

The apparatus 200 comprises a fifth dielectric layer 209. A fourth electrically conductive structure 210 is disposed over a side of the fifth dielectric layer 209, and between the fourth dielectric layer 207 and the fifth dielectric layer 209.

Generally, the second and third electrically conductive structures 206, 208 are at first and second electrical potentials, which are not the same. By contrast, the first and fourth electrically conductive structures 202, 210 are at a third electrical potential, which is different than the first and second electrical potential.

As noted above, more or fewer dielectric layers, or more or fewer electrically conductive structures, or more or fewer dielectric vias, or combinations thereof than those depicted in FIGS. 2A-2B are contemplated by the present teachings, as will become clearer as the present description continues. Moreover, there may be more or fewer different electrical potentials applied to the electrically conductive structures than explicitly described herein. Accordingly, the present teachings are not limited to the number of dielectric layers, or the number of electrically conductive structures, or the number of electrical potentials applied to the electrically conductive structures, or the number of dielectric vias depicted and described in connection with the representative embodiments herein.

Turning to FIG. 2B, the apparatus 200 is depicted in final form after assembly, where the various individual layers are not discerned. As depicted in FIG. 2B, each of the plurality of dielectric vias 204 in the respective first˜fifth dielectric layers 201, 203, 205,207, 209 are aligned to form a continuous dielectric via 204′ along a height (y-direction of the coordinate system depicted) of the apparatus 200.

In accordance with a representative embodiment, the first and fourth electrically conductive structures 202 and 210 are shielding layers, which may be electrically connected to a reference ground; and the second and third electrically conductive layers 206, 208 are windings of an inductor. It is emphasized that the noted implementations of the second and third electrically conductive structures 206, 208 are merely illustrative, and other implementations are contemplated. Just by way of example, and as described in connection with other representative embodiments herein, the second and third electrically conductive structures 206, 208 and similar structures described herein may be inductors, transmission lines, or delay lines, as well as reference ground planes and shielding layers. In yet other embodiments described herein, the various electrically conductive structures may be impedance transformers.

The dielectric vias 204 may include air or some other gas having a comparatively low dielectric constant, or may comprise other known materials having a comparatively low dielectric constant (sometimes referred to as low-k materials). The filling of the dielectric vias 204 with a material other than air may be done by a known method prior to assembly of the apparatus 200. As will be appreciated by one of ordinary skill in the art, the material provided in the dielectric vias 204 is selected based on various design parameters, and especially a desired relative effective permittivity ∈_{r,eff} as described below.

By providing the dielectric vias 204 in regions of the apparatus 200 where the magnitude of the electric field emanating between the second and third electrically conductive structures 206, 208, and between the first and second electrically conductive structures 202, 206, and between the third and fourth electrically conductive structures 208, 210 is comparatively large, the parasitic capacitance between the second and third electrically conductive structures 206, 208, and between the first and second electrically conductive structures 202, 206, and between the third and fourth electrically conductive structures 208, 210 is reduced compared to a structure that does not comprise the dielectric vias 204 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in region 211 of FIG. 2B where the magnitude of the electric field is comparatively high, the dielectric via 204′, which has a low relative permittivity (∈ᵣ₂) compared to the relative permittivity of the second˜fourth dielectric layers 203, 205, 207, provides a reduced relative effective permittivity ∈_{r,eff}, and therefore a reduction of the capacitive parasitics.

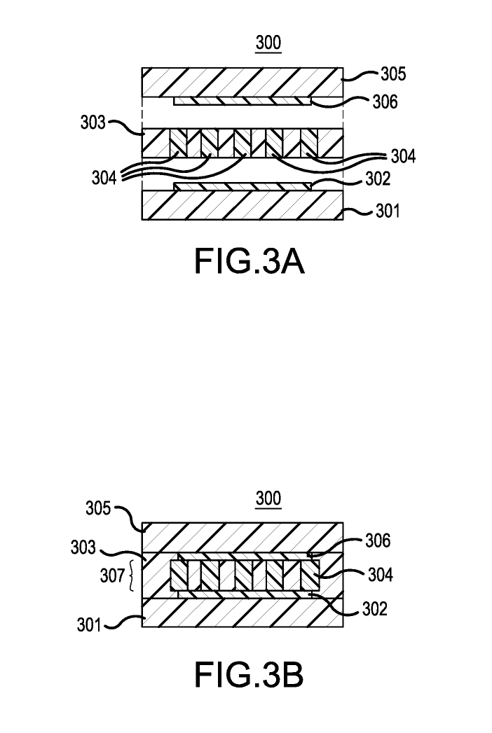

FIGS. 3A-3B depict an apparatus 300 according to a representative embodiment. Notably, many details of the various features described in connection with the representative embodiments of FIGS. 1A-1B and FIGS. 2A-2B are common to those of FIGS. 3A-3B. These details are not necessarily repeated in the description of FIGS. 3A-3B.

FIG. 3A depicts an exploded cross-sectional view of apparatus 300 in accordance with a representative embodiment. Notably, the apparatus 300 may be a portion of a multi-layer structure that is a component of an electronic device or electronic module.

The apparatus 300 comprises a first dielectric layer 301, which has a first electrically conductive structure 302 disposed thereover. A second dielectric layer 303 is disposed over the first electrically conductive structure 302. The second dielectric layer 303 comprises a plurality of dielectric vias 304 disposed therein.

The apparatus 300 further comprises a third dielectric layer 305 disposed over the second dielectric layer 303. A second electrically conductive structure 306 is disposed over one side of the third dielectric layer 305.

Generally, the first and second electrically conductive structures 302, 306 are at first and second electrical potentials, which are not the same.

Notably, more or fewer dielectric layers, or more or fewer electrically conductive structures, or more of fewer dielectric vias, or combinations thereof than those depicted in FIGS. 3A-3B are contemplated by the present teachings, as will become clearer as the present description continues. Moreover, there may be more or fewer different electrical potentials applied to the electrically conductive structures than explicitly described herein. Accordingly, the present teachings are not limited to the number of dielectric layers, or the number of electrically conductive structures, or the number of electrical potentials applied to the electrically conductive structures, or the number of dielectric vias depicted and described in connection with the representative embodiments herein.

Turning to FIG. 3B, the apparatus 300 is depicted in final form after assembly, where the various individual layers are not discerned.

In accordance with a representative embodiment, the first and second electrically conductive structures 302, 306 are windings of an inductor. It is emphasized that the noted implementations of the first and second electrically conductive structures 302, 306 are merely illustrative, and other implementations are contemplated. Just by way of example, and as described in connection with other representative embodiments herein, the first and second electrically conductive structures 302, 306 and similar structures described herein may be inductors, transmission lines, or delay lines, as well as reference ground planes and shielding layers. In yet other embodiments described herein, the various electrically conductive structures may be impedance transformers.

The plurality of dielectric vias 304 may include air or some other gas having a comparatively low dielectric constant, or may comprise other known materials having a comparatively low dielectric constant (sometimes referred to as low-k materials). The filling of the dielectric vias 304 with a material other than air may be done by a known method prior to assembly of the apparatus 300. As will be appreciated by one of ordinary skill in the art, the material provided in the dielectric vias 304 is selected based on various design parameters, and especially a desired relative effective permittivity ∈_{r,eff} as described below.

By providing the dielectric vias 304 in regions of the apparatus 300 where the magnitude of the electric field emanating between the first and second electrically conductive structures 302, 306 is comparatively large, the parasitic capacitance between the first and second electrically conductive structures 302, 306 is reduced compared to a structure that does not comprise the dielectric vias 304 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in region 307 of FIG. 3B where the magnitude of the electric field is comparatively high, the dielectric vias 304, which has a low relative permittivity (∈ᵣ₂) compared to the relative permittivity of the first˜third dielectric layers 301, 303, 305 provides a reduced relative effective permittivity ∈_{r,eff}, and therefore a reduction of the capacitive parasitics.

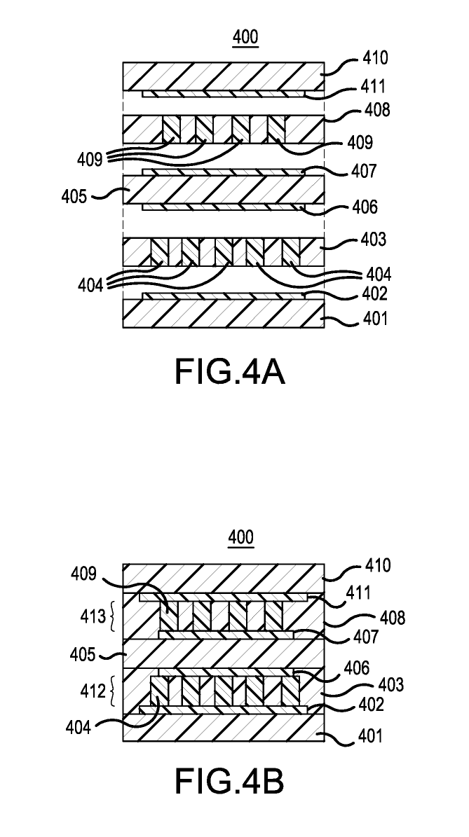

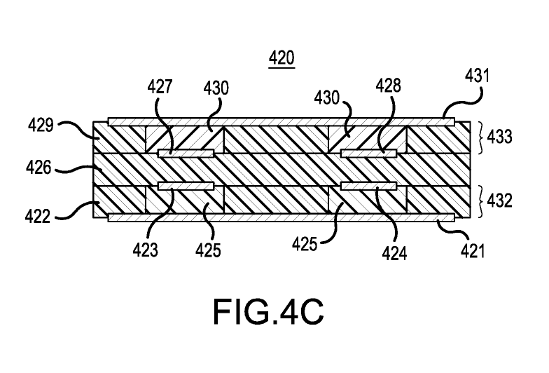

FIGS. 4A-4B depict an apparatus 400 according to a representative embodiment. Notably, many details of the various features described in connection with the representative embodiments of FIGS. 1A-1B, FIGS. 2A-2B, and FIGS. 3A-3B are common to those of FIGS. 4A-4B. These details are not necessarily repeated in the description of FIGS. 4A-4B.

FIG. 4A depicts an exploded cross-sectional view of apparatus 400 in accordance with a representative embodiment. Notably, the apparatus 400 may be a portion of a multi-layer structure that is a component of an electronic device or electronic module.

The apparatus 400 comprises a first dielectric layer 401, which has a first electrically conductive structure 402 disposed thereover. A second dielectric layer 403 is disposed over the first electrically conductive structure 402. The second dielectric layer 403 comprises a first plurality of dielectric vias 404 disposed therein.

The apparatus 400 further comprises a third dielectric layer 405 disposed over the second dielectric layer 403. A second electrically conductive structure 406 is disposed over one side of the third dielectric layer 405, and a third electrically conductive structure 407 is disposed over an opposing side of the third dielectric layer 405.

The apparatus 400 comprises a fourth dielectric layer 408, which comprises a second plurality of dielectric vias 409 disposed therein.

The apparatus 400 comprises a fifth dielectric layer 410, which has a fourth electrically conductive structure 411 disposed thereover.

Generally, the second and third electrically conductive structures 406, 407 are at first and second electrical potentials, which are not the same. By contrast, the first and fourth electrically conductive structures 402, 411 are at a third electrical potential, which is different than the first and second electrical potentials.

Notably, more or fewer dielectric layers, or more or fewer electrically conductive structures, or more of fewer dielectric vias (or combinations thereof) than those depicted in FIGS. 4A-4B are contemplated by the present teachings, as will become clearer as the present description continues. Moreover, there may be more or fewer different electrical potentials applied to the electrically conductive structures than explicitly described herein. Accordingly, the present teachings are not limited to the number of dielectric layers, or the number of electrically conductive structures, or the number of electrical potentials applied to the electrically conductive structures, or the number of dielectric vias depicted and described in connection with the representative embodiments herein.

Turning to FIG. 4B, the apparatus 400 is depicted in final form after assembly, where the various individual layers are not discerned.

In accordance with a representative embodiment, the second and third electrically conductive structures 406, 407 are windings of an inductor, and the first and fourth electrically conductive structures 402, 411 are shielding layers, which may or may not be electrically connected to a reference ground. It is emphasized that the noted implementations of the first˜fourth electrically conductive structures 402, 406, 407, 411 are merely illustrative, and other implementations are contemplated. Just by way of example, and as described in connection with other representative embodiments herein, the first˜fourth electrically conductive structures 402, 406, 407, 411 and similar structures described herein may be inductors, transmission lines, or delay lines, as well as reference ground planes and shielding layers. In yet other embodiments described herein, the various electrically conductive structures may be impedance transformers.

The first and second pluralities of dielectric vias 404, 409 may include air or some other gas having a comparatively low dielectric constant, or may be comprise other known materials having a comparatively low dielectric constant (sometimes referred to as low-k materials). The filling of the first and second pluralities of dielectric vias 404, 409 with a material other than air may be done by a known method prior to assembly of the apparatus 400. As will be appreciated by one of ordinary skill in the art, the material provided in the first and second pluralities of dielectric vias 404, 409 is selected based on various design parameters, and especially a desired relative effective permittivity ∈_{r,eff} as described below.

By providing the first and second pluralities of dielectric vias 404, 409 in regions of the apparatus 400 where the magnitude of the electric fields emanating between the first and second, and third and fourth electrically conductive structures 402, 406, and 407 and 411, respectively, are comparatively large, the parasitic capacitance between the first and second, and third and fourth electrically conductive structures 402, 406, and 407 and 411, respectively, is reduced compared to a structure that does not comprise the first and second pluralities of dielectric vias 404, 409 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in regions 412 and 413 of FIG. 4B where the magnitude of the electric field is comparatively high, the first and second pluralities of dielectric vias 404, 409, respectively, which have a low relative permittivity (∈ᵣ₂) compared to the relative permittivity of the first˜fifth dielectric layers 401, 403, 405, 408 and 410 provides a reduced relative effective permittivity ∈_{r,eff}, and therefore a reduction of the capacitive parasitics.

Turning to FIG. 4C, an apparatus 420 is depicted in final form after assembly. The apparatus shares many common features and details with apparatus 400 of FIGS. 4A-4B. Similarly, many details of the various features described in connection with the representative embodiments of FIGS. 1A-1B, FIGS. 2A-2B, and FIGS. 3A-3B are common to apparatus 420 of FIG. 4C. These details are not necessarily repeated in the description of FIG. 4C.

The apparatus 420 comprises a first electrically conductive structure 421 and a first dielectric layer 422 disposed thereover. The first dielectric layer 422 has a second electrically conductive structure 423 and a third electrically conductive structure 424 disposed thereover, and opposing the first electrically conductive structure 421.

The first dielectric layer 422 comprises a first plurality of dielectric vias 425 disposed therein.

A second dielectric layer 426 is disposed over the first and second electrically conductive structures 423, 424. A fourth electrically conductive structure 427 and a fifth electrically conductive structure 428 are disposed over the second dielectric layer 426.

The apparatus 420 further comprises a third dielectric layer 429 disposed over the second dielectric layer 426. The third dielectric layer 429 comprises a second plurality of dielectric vias 430. A sixth electrically conductive structure 431 is disposed over the third dielectric layer 429, and opposing the fourth and fifth electrically conductive structures 427, 428.

In accordance with a representative embodiment, the first and sixth electrically conductive structures 421, 431 are at a first electrical potential. Moreover, the second, third, fourth and fifth electrically conductive structures 423, 424, 427 and 428 are at second, third, fourth and fifth electrical potentials. The second, third, fourth and fifth electrical potentials are different than the first electrical potential

Notably, more or fewer dielectric layers, or more or fewer electrically conductive structures, or more of fewer dielectric vias (or combinations thereof) than those depicted in FIG. 4C are contemplated by the present teachings, as will become clearer as the present description continues. Moreover, there may be more or fewer different electrical potentials applied to the electrically conductive structures than explicitly described herein. Accordingly, the present teachings are not limited to the number of dielectric layers, or the number of electrically conductive structures, or the number of electrical potentials applied to the electrically conductive structures, or the number of dielectric vias depicted and described in connection with the representative embodiments herein.

In accordance with a representative embodiment, the second, third, fourth and fifth electrically conductive structures 423, 424, 427 and 428 are windings of an inductor, and the first and sixth electrically conductive structures 421, 431 are reference ground layers. It is emphasized that the noted implementations of the first˜sixth electrically conductive structures 421, 423, 424, 427, 428 and 431 are merely illustrative, and other implementations are contemplated. Just by way of example, and as described in connection with other representative embodiments herein, the first˜sixth electrically conductive structures 421, 423,424,427,428 and 431 and similar structures described herein may be inductors, transmission lines, or delay lines, as well as reference ground planes and shielding layers. In yet other embodiments described herein, the various electrically conductive structures may be impedance transformers.

The first and second pluralities of dielectric vias 425, 430 may include air or some other gas having a comparatively low dielectric constant, or may be comprise other known materials having a comparatively low dielectric constant (sometimes referred to as low-k materials). The filling of the first and second pluralities of dielectric vias 425, 430 with a material other than air may be done by a known method prior to assembly of the apparatus 420. As will be appreciated by one of ordinary skill in the art, the material provided in the first and second pluralities of dielectric vias 425, 430 is selected based on various design parameters, and especially a desired relative effective permittivity ∈_{r,eff} as described below.

By providing the first and second pluralities of dielectric vias 425,430 in regions of the apparatus 420 where the magnitude of the electric fields emanating between the first˜sixth electrically conductive structures 421, 423, 424, 427, 428 and 431, respectively, are comparatively large, the parasitic capacitances between the first, and second and third electrically conductive structures 421, and 423 and 424, and between the sixth, and fourth and fifth electrically conductive structures 431, and 427 and 428, are reduced compared to a structure that does not comprise the first and second pluralities of dielectric vias 425, 430 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in regions 432 and 433 of FIG. 4C where the magnitude of the electric field is comparatively high, the first and second pluralities of dielectric vias 425, 430, respectively, which have a low relative permittivity (∈ᵣ₂) compared to the relative permittivity of the first˜third dielectric layers 422, 426, 429 provides a reduced relative effective permittivity ∈_{r,eff}, and therefore a reduction of the capacitive parasitics.

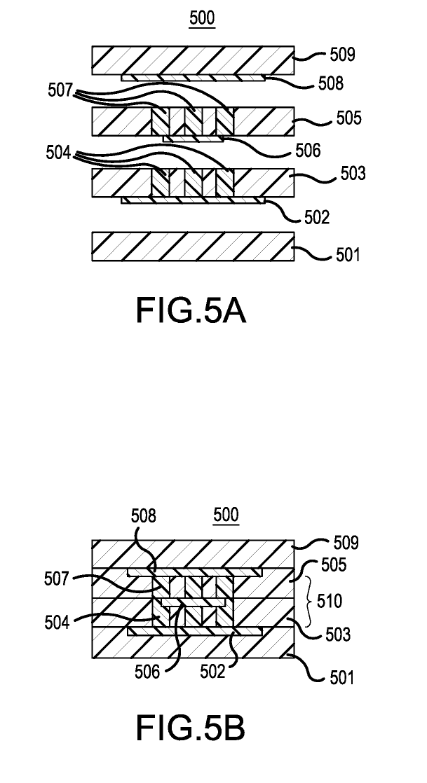

FIGS. 5A-5B depict an apparatus 500 according to a representative embodiment. Notably, many details of the various features described in connection with the representative embodiments of FIGS. 1A-1B, FIGS. 2A-2B, FIGS. 3A-3B, and FIGS. 4A-4B are common to those of FIGS. 5A-5B. These details are not necessarily repeated in the description of FIGS. 5A-5B.

FIG. 5A depicts an exploded cross-sectional view of apparatus 500 in accordance with a representative embodiment. Notably, the apparatus 500 may be a portion of a multi-layer structure that is a component of an electronic device or electronic module.

The apparatus 500 comprises a first dielectric layer 501, which has a first electrically conductive structure 502 disposed thereover. A second dielectric layer 503 is disposed over the first electrically conductive structure 502. The second dielectric layer 503 comprises a first plurality of dielectric vias 504 disposed therein.

The apparatus 500 further comprises a third dielectric layer 505 disposed over the second dielectric layer 503. A second electrically conductive structure 506 is disposed over the third dielectric layer 505, and a second plurality of dielectric vias 507 is disposed in the third dielectric layer 505.

The apparatus 500 comprises a forth dielectric layer 509, which has a third electrically conductive structure 508 disposed thereover.

Notably, more or fewer dielectric layers, or more or fewer electrically conductive structures, or more of fewer dielectric vias (or combinations thereof) than those depicted in FIGS. 5A-5B are contemplated by the present teachings, as will become clearer as the present description continues. Moreover, there may be more or fewer different electrical potentials applied to the electrically conductive structures than explicitly described herein. Accordingly, the present teachings are not limited to the number of dielectric layers, or the number of electrically conductive structures, or the number of electrical potentials applied to the electrically conductive structures, or the number of dielectric vias depicted and described in connection with the representative embodiments herein.

Turning to FIG. 5B, the apparatus 500 is depicted in final form after assembly, where the various individual layers are not discerned.

In accordance with a representative embodiment, the first and third electrically conductive structures 502, 508 are reference ground planes, and the second electrically conductive structures 506 is a signal transmission line. Generally, the second electrically conductive structure 506 is at a first electrical potential, and the first and third electrically conductive structures 502, 508 are at a second electrical potential, which is different than the first electrical potential.

As will be appreciated by one of ordinary skill in the art, the configuration the first, second and third electrically conductive structures 502, 506 and 508, separated by second, and third dielectric layers 503, 505 provides a stripline signal transmission line. It is emphasized that the noted implementations of the first˜third electrically conductive structures 502, 506, 508 are merely illustrative, and other implementations are contemplated. Just by way of example, and as described in connection with other representative embodiments herein, the first˜third electrically conductive structures 502, 506, 508 and similar structures described herein may be inductors, other types of transmission lines, or delay lines, as well as reference ground planes and shielding layers. In yet other embodiments described herein, the various electrically conductive structures may be impedance transformers.

The first and second pluralities of dielectric vias 504, 507 may include air or some other gas having a comparatively low dielectric constant, or may be comprise other known materials having a comparatively low dielectric constant (sometimes referred to as low-k materials). The filling of the first and second pluralities of dielectric vias 504, 507 with a material other than air may be done by a known method prior to assembly of the apparatus 500. As will be appreciated by one of ordinary skill in the art, the material provided in the first and second pluralities of dielectric vias 504, 507 is selected based on various design parameters, and especially a desired relative effective permittivity ∈_{r,eff} as described below.

By providing the first and second pluralities of dielectric vias 504, 507 in regions of the apparatus 500 where the magnitude of the electric fields emanating between the first and second, and the second and third electrically conductive structures 502, 506, and 506 and 508, respectively, are comparatively large, the parasitic capacitance between the first and second, and the second and third electrically conductive structures 502, 506, and 506 and 508, respectively, is reduced compared to a structure that does not comprise the dielectric vias 504, 507 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in region 510 of FIG. 5B where the magnitude of the electric field is comparatively high, the first and second pluralities of dielectric vias 504, 507, respectively, which have a low relative permittivity (∈ᵣ₂) compared to the relative permittivity of the first˜forth dielectric layers 501, 503, 505, and 509 provides a reduced relative effective permittivity ∈_{r,eff}, and therefore a reduction of the capacitive parasitics.

FIGS. 6A-6F are cross-sectional views of various layers of an apparatus according to a representative embodiment. Notably, many details of the various features described in connection with the representative embodiments of FIGS. 1A-1B, FIGS. 2A-2B, FIGS. 3A-3B, FIGS. 4A-4B, and FIG. 5A-5B are common to those of FIGS. 6A-6F. These details are not necessarily repeated in the description of FIGS. 6A-6F.

FIGS. 6A-6F each depict dielectric layer 601 with various arrangements of first and second electrically conductive structures 603, 604, and one or more dielectric vias (e.g., dielectric via 602) disposed in dielectric layer 601. As in other representative embodiments described herein, the first and second electrically conductive structures 603, 604 may be one of a variety of electrical components, including, but not limited to inductors, transmission lines, or delay lines, as well as reference ground planes and shielding layers. In yet other embodiments described herein, the first and second electrically conductive structures 603, 604 may be impedance transformers.

Generally, the first and second electrically conductive structures 603, 604 are at first and second electrical potentials, which are not the same.

The various arrangements depicted in FIGS. 6A-6F are contemplated for use in apparatuses, such as those described above, and further herein. Stated somewhat differently, the various representative embodiments of FIGS. 6A-6F are contemplated to be a layer of a multi-layer substrate used in an electronic module or similar structure, by way of example. It is emphasized that this contemplated implementation of the various embodiments of FIGS. 6A-6F is merely illustrative, and other implementations are contemplated.

Generally, in the representative embodiments of FIGS. 6A-6F, the first and second electrically conductive structures 603, 604 are provided in a vertical arrangement with the dielectric layer 601, or one or more of first˜third dielectric vias 602, 605,606, or both disposed therebetween.

Like representative embodiments described more fully above, the representative embodiments of FIGS. 6A-6F have one or more dielectric vias 602, 605, 606 disposed in regions of the dielectric layer 601 where the magnitude of the electric fields emanating between the first and second electrically conductive structures 603, 604, respectively, are comparatively large. Thereby, the parasitic capacitance between the first and second electrically conductive structures 603, 604 is reduced compared to a structure that does not comprise the dielectric vias 602, 605, 606 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in regions where the magnitude of the electric field is comparatively high, the dielectric vias 602, 605, 606, which have a low relative permittivity (∈ᵣ₂) compared to the relative permittivity of the dielectric layer 601 provides a reduced relative effective permittivity ∈_{r,eff}, and therefore a reduction of the capacitive parasitics.

It is noted that the dielectric vias 602, 605, 606 are disposed at in the same dielectric layer (i.e., on the same plane). However, the dielectric vias 602, 605, 606 may be transposed and therefore the dielectric via(s) at the left side is/are not visible in this cross-section.

Turning to FIG. 6A, dielectric via 602 is offset with ends of the respective first and second electrically conductive structures 603, 604 extending over the dielectric via 602 as shown.

By way of example, the first and second electrically conductive structures 603, 604 may be part of a wound two layer inductor (where the other part of the winding is not shown in FIG. 6A). In this case, the current will mainly flow at the one side (i.e., the current flows mainly along the inner side of the loops (windings)) of the first and second electrically conductive structures 603, 604 and therefore the dielectric via 602 is beneficially located along the side where current mainly flows to thereby reduce the parasitic capacitance between the first and second electrically conductive structures 603, 604.

Finally, and among other benefits, providing dielectric via 602 on only one side of the first and second electrically conductive structures 603, 604 allows compliance with design rules, such as spacing of dielectric via and module edge, and minimum pitch of dielectric vias, to name only a few.

Turning to FIG. 6B, dielectric vias 602, 605 are disposed at respective ends of the respective first and second electrically conductive structures 603, 604, with these ends extending over the dielectric vias 602, 605 as shown. As is known, because current in the first and second electrically conductive structures 603, 604 is located primarily at the surface, the electric field is comparatively large at the ends, which are shown to extend over the dielectric vias 602, 605. Accordingly, by placing the dielectric vias 602, 605 so that the ends of the first and second electrically conductive structures 603, 604 are disposed thereover, the regions where the magnitude of the electric field is relatively large include the dielectric vias 602, 605, which have a low relative permittivity (∈ᵣ₂) compared to the relative permittivity of the dielectric layer 601. As such, the dielectric vias 602, 605 provide a reduced relative effective permittivity ∈_{r,eff}, and therefore a reduction of the capacitive parasitics.

Turning to FIG. 6C, dielectric vias 602, 605, 606 are disposed between and extending past the ends of respective first and second electrically conductive structures 603, 604. As described above, the regions where the magnitude of the electric field is relatively large, the dielectric vias 602, 605, which have a low relative permittivity (∈ᵣ₂) compared to the relative permittivity of the dielectric layer 601, provide a reduced relative effective permittivity ∈_{r,eff}, and therefore a reduction of the capacitive parasitics. Furthermore, the dielectric via 606 located near the center of the first and second electrically conductive structures 603, 604 the further reduces the relative effective permittivity ∈_{r,eff} by providing more material with a comparatively low relative permittivity (∈ᵣ₂), and therefore further reduces the deleterious parasitic capacitive effects.

Turning to FIG. 6D, dielectric vias 602, 605 are disposed at overlapping ends of the respective first and second electrically conductive structures 603, 604, with these ends extending over the dielectric vias 602, 605 as shown. By placing the dielectric vias 602, 605 so that the overlapping ends of the first and second electrically conductive structures 603, 604 are disposed thereover, the regions where the magnitude of the electric field is relatively large, the dielectric vias 602, 605, which have a low relative permittivity (∈ᵣ₂) compared to the relative permittivity of the dielectric layer 601, provide a reduced relative effective permittivity ∈_{r,eff}, and therefore a reduction of the capacitive parasitics. The apparatus depicted in FIG. 6D depicts the adaptability of the present teachings to accommodate for situations where the first and second electrically conductive structures 603, 604 are misaligned, for example due to design constraints or the footprint of the conductive structures, for example. By way of example, the first and second electrically conductive structures 603, 604 may be portions of respective inductors, which are beneficially offset to reduce interaction therebetween. Nonetheless, the apparatus of FIG. 6D enables a reduction in the reduced relative effective permittivity ∈_{r,eff}.

Turning to FIG. 6E, dielectric via 602 is disposed to extend beneath overlapping ends of the respective first and second electrically conductive structures 603, 604, with these ends extending over the dielectric via 602 as shown. By placing the dielectric via 602 so that the overlapping ends of the first and second electrically conductive structures 603, 604 are disposed thereover, the regions where the magnitude of the electric field is relatively large, the dielectric via 602, which have a low relative permittivity (∈ᵣ₂) compared to the relative permittivity of the dielectric layer 601, provide a reduced relative effective permittivity ∈_{r,eff}, and therefore a reduction of the capacitive parasitics. Moreover, the apparatus depicted in FIG. 6E depicts the adaptability of the present teachings to accommodate for situations where the first and second electrically conductive structures 603, 604 are misaligned, and only one dielectric via can be provided, for example due to design constraints or the footprint of the conductive structures, for example. Like the example described in connection with FIG. 6D, the first and second electrically conductive structures 603, 604 may be portions of respective inductors, which are beneficially offset to reduce interaction therebetween. Nonetheless, the apparatus of FIG. 6D enables a reduction in the reduced relative effective permittivity ∈_{r,eff}. Furthermore, the comparatively voluminous dielectric via 602 further reduces the relative effective permittivity ∈_{r,eff} by providing more material with a comparatively low relative permittivity (∈ᵣ₂), further reduces the deleterious parasitic capacitive effects.

Turning to FIG. 6F, dielectric via 602 is disposed to extend entirely beneath the first and second electrically conductive structures 603, 604 with both ends thereof extending over the dielectric via 602 as shown. By way of example, the apparatus depicts first and second electrically conductive structures 603, 604 having a line-width (x-direction in the coordinate system depicted) that is comparatively small to realize a comparatively high inductance. However, the minimum width/diameter of the dielectric via 602 is greater than the line-width by choice, or because of design constraints or manufacturing limitations regarding the minimum size of the dielectric vias. Again, by placing the dielectric via 602 so that the entire the first and second electrically conductive structures 603, 604 are disposed thereover, the regions where the magnitude of the electric field is relatively large corresponds to the location of the dielectric via 602, which has a low relative permittivity (∈ᵣ₂) compared to the relative permittivity of the dielectric layer 601. As such, the dielectric via 602 provides a reduced relative effective permittivity ∈_{r,eff}, and therefore a reduction of the capacitive parasitics. Furthermore, the comparatively voluminous dielectric via 602 further reduces the relative effective permittivity ∈_{r,eff} by providing more material with a comparatively low relative permittivity (∈ᵣ₂), further reduces the deleterious parasitic capacitive effects.

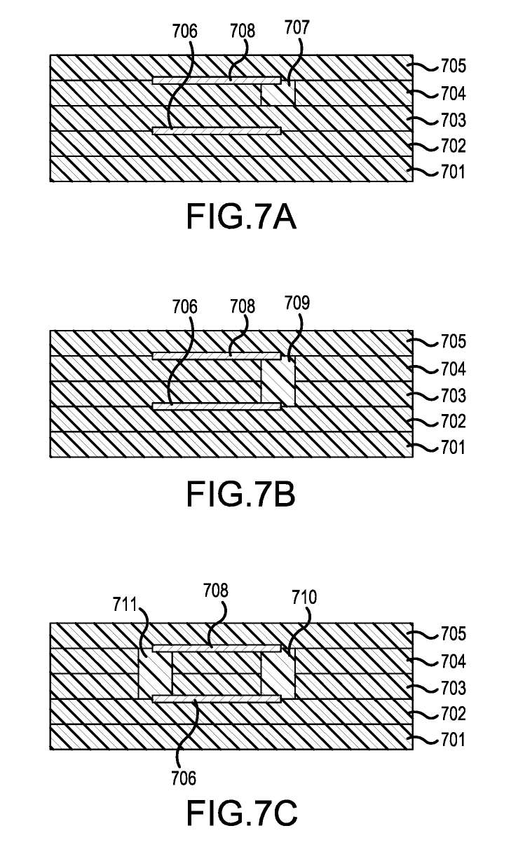

FIGS. 7A-7G are cross-sectional views of various layers of an apparatus according to a representative embodiment. Notably, many details of the various features described in connection with the representative embodiments of FIGS. 1A-1B, FIGS. 2A-2B, FIGS. 3A-3B, FIGS. 4A-4B, FIG. 5A-5B and FIGS. 6A-6F are common to those of FIGS. 7A-7G. These details are not necessarily repeated in the description of FIGS. 7A-7G.

Notably, each of FIGS. 7A-7G depicts an apparatus comprising a multi-layer structure comprising first through fifth dielectric layers 701-705 with various arrangements of first and second electrically conductive structures 706, 708, and one or more dielectric vias (e.g., dielectric via 709) disposed in one or more of the first through fifth dielectric layers 701-705. As in other representative embodiments described herein, the first and second electrically conductive structures 706, 708 may be one of a variety of electrical components, including, but not limited to inductors, transmission lines, or delay lines, as well as reference ground planes and shielding layers. In yet other embodiments described herein, the first and second electrically conductive structures 706, 708 may be impedance transformers.

Generally, the first and second electrically conductive structures 706, 708 are at first and second electrical potentials, which are not the same.

The various arrangements depicted in FIGS. 7A-7G are contemplated for use in apparatuses, such as those described above, and further herein. Stated somewhat differently, the various representative embodiments of FIGS. 7A-7G are contemplated to be a multi-layer substrate used in an electronic module or similar structure, by way of example. It is emphasized that this contemplated implementation of the various embodiments of FIGS. 7A-7F is merely illustrative, and other implementations are contemplated.

Generally, in the representative embodiments of FIGS. 7A-7G, the first and second electrically conductive structures 706, 708 are provided in a vertical arrangement with the one or more of the first through fifth dielectric layers 701-705, or one or more dielectric vias, or combinations thereof, disposed therebetween.

Like representative embodiments described more fully above, the representative embodiments of FIGS. 7A-7G have one or more dielectric vias disposed in regions of the multi-layer structure where the magnitude of the electric fields emanating between the first and second electrically conductive structures 706, 708, respectively, are comparatively large. Thereby, the parasitic capacitance between the first and second electrically conductive structures 706, 708 is reduced compared to a structure that does not comprise the dielectric vias of the representative embodiments. As noted above, unmitigated parasitic capacitance results in an undesired reduction in the characteristic impedance and/or an undesired reduction in the inductance of an electronic component (e.g., transmission line or inductor).

Stated somewhat differently, in regions where the magnitude of the electric field is comparatively high, the dielectric vias, which have a low relative permittivity (∈ᵣ₂) compared to the relative permittivity of the first through fifth dielectric layers 701-705, provide a reduced relative effective permittivity ∈_{r,eff}, and therefore a reduction of the capacitive parasitics.

Turning to FIG. 7A, a dielectric via 707 is disposed in the fourth dielectric layer 704, and extends past the one end of each of the first and second electrically conductive structures 706, 708. Notably, the first and second electrically conductive structures 706, 708 are separated by two dielectric layers, with the dielectric via 707 provided in only one. Notably, the dielectric via 707 does not extend completely between the first and second electrically conductive structures 706, 708, but rather only partially. The partial extension of the dielectric via 707 may be due to design or manufacturing constraints. Yet, by placing the dielectric via 707 at least partially between the first and second electrically conductive structures 706, 708, a reduction in the reduced relative effective permittivity ∈_{r,eff} therebetween is realized.

Turning to FIG. 7B, a dielectric via 709 is disposed in the third and fourth dielectric layers 703, 704, and extend past one end on each of the first and second electrically conductive structures 706, 708. Notably, the first and second electrically conductive structures 706, 708 are separated by two dielectric layers, with the dielectric via 709 provided in each of the separating dielectric layers. Notably, the dielectric via 709 in each of the intervening dielectric layers 703, 704 is not necessarily completely or even partially aligned. Rather a dielectric via can be provided in dielectric layer 703, that is misaligned with respect to the dielectric via in dielectric layer 704. Beneficially, the dielectric via 709 disposed between even a portion of the first and second electrically conductive structures 706, 708 reduces the relative effective permittivity ∈_{r,eff} therebetween.

Turning to FIG. 7C, dielectric vias 710, 711 are disposed in the third and fourth dielectric layers 703, 704, and extend past each end on both of the first and second electrically conductive structures 706, 708. Notably, the first and second electrically conductive structures 706, 708 are separated by two dielectric layers, with the dielectric vias 710, 711 provided in each of the separating dielectric layers.

By placing the dielectric vias 710, 711 so that the ends of the first and second electrically conductive structures 706, 708 are disposed thereover, the regions where the magnitude of the electric field is relatively large include the dielectric vias 710, 711, which have a low relative permittivity (∈ᵣ₂) compared to the relative permittivity of the dielectric third and fourth dielectric layers 703, 704. As such, the dielectric vias 710, 711 provide a reduced relative effective permittivity ∈_{r,eff}, and therefore a reduction of the capacitive parasitics. Moreover, the dielectric vias 710, 711 are not necessarily completely or even partially aligned. Rather the dielectric vias 710, 711 can be provided in third and fourth dielectric layers 703, 704 misaligned with respect to one another.

Turning to FIG. 7D, dielectric via 712 is disposed in the third dielectric layer 703, and extends past one end of both of the first and second electrically conductive structures 706, 708. Notably, the first and second electrically conductive structures 706, 708 are separated by three dielectric layers, with the dielectric via 712 provided in one of the separating dielectric layers. As such, the dielectric via 712 does not extend completely between the first and second electrically conductive structures 706, 708, but rather only partially. The partial extension of the dielectric via 712 may be due to design or manufacturing constraints. Yet, by placing the dielectric via 712 at least partially between the first and second electrically conductive structures 706,708, a reduction in the reduced relative effective permittivity ∈_{r,eff} therebetween is realized.

Turning to FIG. 7E, dielectric vias 713, 714 are disposed in the third and fourth dielectric layers 703, 704, and second and third dielectric layers 702, 703, respectively, and extend past each end on both of the first and second electrically conductive structures 706, 708. Notably, the first and second electrically conductive structures 706, 708 are separated by three dielectric layers, with the dielectric vias 713, 714 each provided in two of the separating dielectric layers. As such, the dielectric vias 713, 714 do not extend completely between the first and second electrically conductive structures 706, 708, but rather only partially. The partial extension of the dielectric vias 713, 714 may be due to design or manufacturing constraints. Yet, by placing the dielectric vias 713,714 at least partially between the first and second electrically conductive structures 706, 708, a reduction in the reduced relative effective permittivity ∈_{r,eff} therebetween is realized. Finally, as described above, it is not necessary that the dielectric via 713 disposed in each of the separating dielectric layers 703, 704 be completely aligned to each other. Rather, the dielectric via in dielectric layer 703 can also be misaligned regarding the dielectric via in dielectric layer 704. Similarly the dielectric via 714 in each of the separating dielectric layers 702, 703 can also be misaligned.

Turning to FIG. 7F, dielectric vias 715, 716 are second through fourth dielectric layers 702, 704, and extend past each end of both of the first and second electrically conductive structures 706, 708. Notably, the first and second electrically conductive structures 706, 708 are separated by three dielectric layers, with the dielectric vias 715, 716 provided in at least one of the separating dielectric layers. As described above, for example in connection with the apparatus of FIG. 6B, by placing the dielectric vias 715, 716 so that the ends of the first and second electrically conductive structures 706, 708 are disposed thereover, the regions where the magnitude of the electric field is relatively large include the dielectric vias 715, 716, which have a low relative permittivity (∈ᵣ₂) compared to the relative permittivity of the dielectric layers 702˜704. As such, the dielectric vias 715, 716 provide a reduced relative effective permittivity ∈_{r,eff}, and therefore a reduction of the capacitive parasitics. Finally, as described above, it is not necessary that the dielectric via 715 in each of the separating dielectric layers 702˜704 are completely aligned to each other. Rather, the dielectric via in dielectric layer 703 can also be misaligned regarding the dielectric via in dielectric layer 704, for example. Similarly the dielectric via 716 in one or more of the separating dielectric layers 702˜704 can also be misaligned.

Turning to FIG. 7G, dielectric via 717 is disposed to extend entirely beneath the first and second electrically conductive structures 706, 708 with both ends thereof extending over the dielectric via 717 as shown. The dielectric via 717 is disposed in each of the second through fourth dielectric layers 702˜704. Like the structure described in connection with FIG. 6F, the apparatus of FIG. 7G the first and second electrically conductive structures 706, 708 may have a line-width (x-direction in the coordinate system depicted) that is comparatively small to realize a comparatively high inductance. However, the minimum width/diameter of the dielectric via 717 is greater than the line-width by choice, or because of design constraints or manufacturing limitations regarding the minimum size of the dielectric vias. By placing the dielectric via 717 so that the entire the first and second electrically conductive structures 706, 708 are disposed thereover, the regions where the magnitude of the electric field is relatively large substantially coincides with the dielectric via 717, which has a low relative permittivity (∈ᵣ₂) compared to the relative permittivity of the second through fourth dielectric layers 702˜704. As such, the dielectric via 717 provides a reduced relative effective permittivity ∈_{r,eff}, and therefore a reduction of the capacitive parasitics. Furthermore, the comparatively voluminous dielectric via 602 further reduces the relative effective permittivity ∈_{r,eff} by providing more material with a comparatively low relative permittivity (∈ᵣ₂), further reduces the deleterious parasitic capacitive effects.

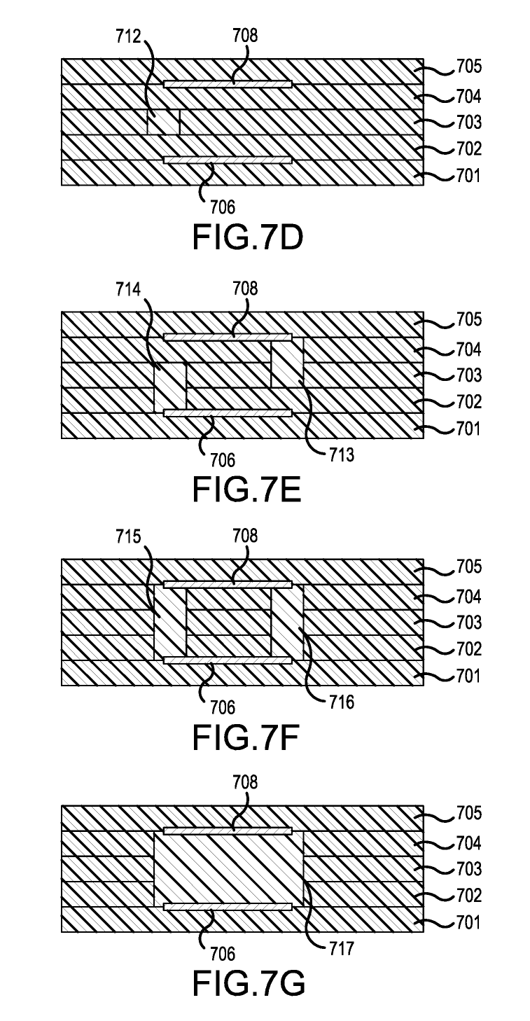

FIGS. 8A-8D are cross-sectional views of various layers of an apparatus according to a representative embodiment. Notably, many details of the various features described in connection with the representative embodiments of FIGS. 1A-1B, FIGS. 2A-2B, FIGS. 3A-3B, FIGS. 4A-4B, FIGS. 5A-5B, FIGS. 6A-6F and FIGS. 7A-7G are common to those of the representative embodiments of FIGS. 8A-8D. These details are not necessarily repeated in the description of FIGS. 8A-8D.

Notably, each of FIGS. 8A-8D depicts dielectric layer 801 with various arrangements of first and second electrically conductive structures 802, 804, and one or more dielectric vias (e.g., dielectric via 803) disposed in dielectric layer 801. As in other representative embodiments described herein, the first and second electrically conductive structures 802, 804 may be one of a variety of electrical components, including, but not limited to inductors, transmission lines, or delay lines, as well as reference ground planes and shielding layers. In yet other embodiments described herein, the first and second electrically conductive structures 802,804 may be impedance transformers.

Generally, the first and second electrically conductive structures 802, 804 are at first and second electrical potentials, which are not the same.

The various arrangements depicted in FIGS. 8A-8D are contemplated for use in apparatuses, such as those described above, and further herein. Stated somewhat differently, the various representative embodiments of FIGS. 8A-8D are contemplated to be one layer of a multi-layer substrate used in an electronic module or similar structure, by way of example. It is emphasized that this contemplated implementation of the various embodiments of FIGS. 8A-8D is merely illustrative, and other implementations are contemplated.

Generally, in the representative embodiments of FIGS. 8A-8D, the first and second electrically conductive structures 802, 804 are provided in a lateral arrangement. As such, the first and second electrically conductive structures 802, 804 are at the same level (i.e., substantially co-planar). Stated somewhat differently, the first and second electrically conductive structures 802, 804 are disposed over the same side of the dielectric layer 801, with one or more dielectric vias 803, 805, 806, 807 disposed therebetween.

Like representative embodiments described more fully above, the representative embodiments of FIGS. 8A-8D have one or more dielectric vias 803, 805, 806, 807 disposed in regions of the dielectric layer 801 where the magnitude of the electric fields emanating between the first and second electrically conductive structures 802, 804, respectively, are comparatively large. Thereby, the parasitic capacitance between the first and second electrically conductive structures 802,804 is reduced compared to a structure that does not comprise the dielectric vias 803, 805, 806, 807 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in regions where the magnitude of the electric field is comparatively high, the dielectric vias 803, 805, 806, 807, which have a low relative permittivity (∈ᵣ₂) compared to the relative permittivity of the dielectric layer 801 provides a reduced relative effective permittivity ∈_{r,eff}, and therefore a reduction of the capacitive parasitics.

Turning to FIG. 8A, dielectric via 803 is disposed substantially equidistant from inner ends the respective first and second electrically conductive structures 802, 804. More generally, the dielectric via 803 may be disposed between the first and second electrically conductive structures 802, 804. By placing the dielectric via 803 between the first and second electrically conductive structures 802, 804, the regions where the magnitude of the electric field is relatively large corresponds to the location of the dielectric via 802, which has a low relative permittivity (∈ᵣ₂) compared to the relative permittivity of the dielectric layer 801. As such, the dielectric via 802 provides a reduced relative effective permittivity ∈_{r,eff}, and therefore a reduction of the capacitive parasitics.

By way of example, the first and second electrically conductive structures 802, 804 may be first and second inductors, with reduced capacitive coupled by virtue of the present teachings. Alternatively the first and second electrically conductive structures 802, 804 may be components of a slot transmission line with the characteristic impedance thereof set by the implementation of the dielectric via 803 to address a design requirement, or to enable relaxation of production tolerances.

Turning to FIG. 8B, dielectric vias 803, 805 are disposed at respective inner ends of the respective first and second electrically conductive structures 802, 804, with these ends extending over the dielectric vias 803, 805 as shown. As is known, because current in the first and second electrically conductive structures 802, 804 is located primarily at the surface, the electric field is comparatively large at the ends, which are shown to extend over the dielectric vias 803, 805. Accordingly, by placing the dielectric vias 803, 805 so that the ends of the first and second electrically conductive structures 802, 804 are disposed thereover, the regions where the magnitude of the electric field is relatively large include the dielectric vias 803, 805, which have a low relative permittivity (∈ᵣ₂) compared to the relative permittivity of the dielectric layer 801. As such, the dielectric vias 803, 805 provide a reduced relative effective permittivity ∈_{r,eff}, and therefore a reduction of the capacitive parasitics.

Turning to FIG. 8C, dielectric vias 803, 805, 806 are disposed between and extending past the ends of respective first and second electrically conductive structures 802, 804. As described above, the regions where the magnitude of the electric field is relatively large, the dielectric vias 803, 805, 806, which have a low relative permittivity (∈ᵣ₂) compared to the relative permittivity of the dielectric layer 801, provide a reduced relative effective permittivity ∈_{r,eff}, and therefore a reduction of the capacitive parasitics.

Turning to FIG. 8D, dielectric via 807 is disposed to extend entirely beneath the first and second electrically conductive structures 802,804 with both ends thereof extending over the dielectric via 807 as shown. By way of example, the apparatus depicts first and second electrically conductive structures 802, 804 having a gap-width, meaning gap between conductive structures 802 and 804 (x-direction in the coordinate system depicted) that is comparatively small to realize a high package density. However, the minimum width/diameter of the dielectric via 807 is greater than the gap-width by choice, or because of design constraints or manufacturing limitations regarding the minimum size of the dielectric vias. Again, by placing the dielectric via 807 so that the entire the first and second electrically conductive structures 802, 804 are disposed thereover, the regions where the magnitude of the electric field is relatively large corresponds to the location of the dielectric via 807, which has a low relative permittivity (∈ᵣ₂) compared to the relative permittivity of the dielectric layer 801. As such, the dielectric via 807 provides a reduced relative effective permittivity ∈_{r,eff}, and therefore a reduction of the capacitive parasitics. Furthermore, the comparatively voluminous dielectric via 807 further reduces the relative effective permittivity ∈_{r,eff} by providing more material with a comparatively low relative permittivity (∈ᵣ₂), further reduces the deleterious parasitic capacitive effects.

Turning to FIG. 8E, dielectric via 803 is disposed beneath an electrically conductive structure 808, an end of which extending over the dielectric via 803 as shown. In this representative embodiment, an electrically conductive via 809 is disposed in the dielectric layer 801. This electrically conductive via 809 may function as a reference ground, for example. By placing the dielectric via 803 between the electrically conductive structure 808 and the electrically conductive via 809, the regions where the magnitude of the electric field is relatively large corresponds to the location of the dielectric via 803, which has a low relative permittivity (∈ᵣ₂) compared to the relative permittivity of the dielectric layer 801. As such, the dielectric via 803 provides a reduced relative effective permittivity ∈_{r,eff}, and therefore a reduction of the capacitive parasitics.

Turning to FIG. 8F, dielectric via 803 is disposed between the electrically conductive structure 808 and the electrically conductive via 809. By placing the dielectric via 803 between the electrically conductive structure 808 and the electrically conductive via 809, the regions where the magnitude of the electric field is relatively large corresponds to the location of the dielectric via 803, which has a low relative permittivity (∈ᵣ₂) compared to the relative permittivity of the dielectric layer 801. As such, the dielectric via 803 provides a reduced relative effective permittivity ∈_{r,eff}, and therefore a reduction of the capacitive parasitics.

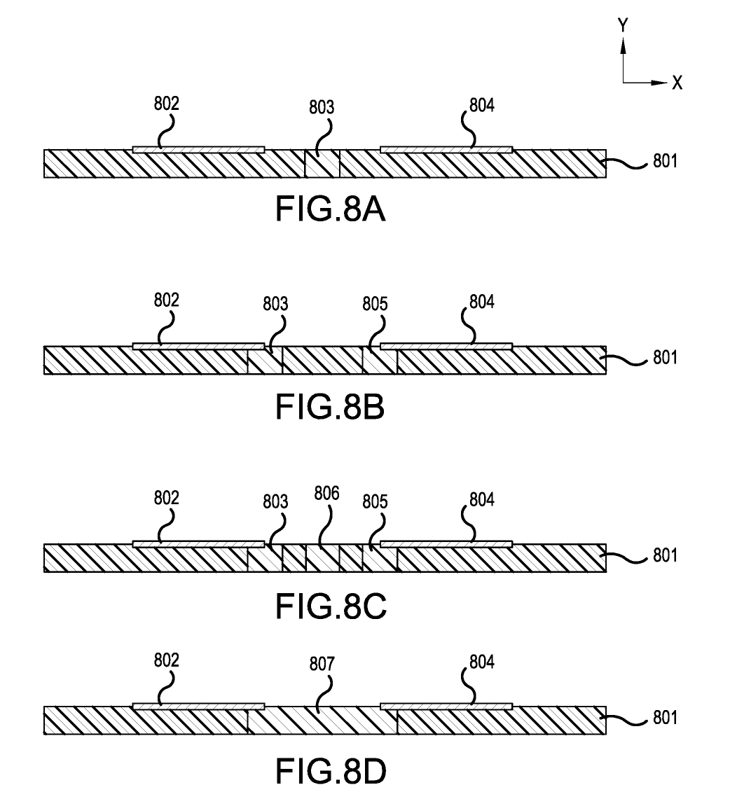

FIGS. 9A-9D are cross-sectional views of various layers of an apparatus according to a representative embodiment. Notably, many details of the various features described in connection with the representative embodiments of FIGS. 1A-1B, FIGS. 2A-2B, FIGS. 3A-3B, FIGS. 4A-4B, FIGS. 5A-5B, FIGS. 6A-6F, FIGS. 7A-7G, and FIGS. 8A-8D are common to those of the representative embodiments of FIGS. 9A-9D. These details are not necessarily repeated in the description of FIGS. 9A-9D.

Notably, each of FIGS. 9A-9D depicts an apparatus comprising a multi-layer structure comprising first through fourth dielectric layers 901-904 with various arrangements of first and second electrically conductive structures 906, 908, and one or more dielectric vias (e.g., dielectric via 909) disposed in one or more of the first through fourth dielectric layers 901-904. As in other representative embodiments described herein, the first and second electrically conductive structures 906, 908 may be one of a variety of electrical components, including, but not limited to inductors, transmission lines, or delay lines, as well as reference ground planes and shielding layers. In yet other embodiments described herein, the first and second electrically conductive structures 906, 908 may be impedance transformers.

Generally, the first and second electrically conductive structures 906, 908 are at first and second electrical potentials, which are not the same.

The various arrangements depicted in FIGS. 9A-9D are contemplated for use in apparatuses, such as those described above, and further herein. Stated somewhat differently, the various representative embodiments of FIGS. 9A-9D are contemplated to be a multi-layer substrate used in an electronic module or similar structure, by way of example. It is emphasized that this contemplated implementation of the various embodiments of FIGS. 9A-9D is merely illustrative, and other implementations are contemplated.

Generally, in the representative embodiments of FIGS. 9A-9D, the first and second electrically conductive structures 906, 908 are provided in a lateral arrangement. As such, the first and second electrically conductive structures 906, 908 are at the same level (i.e., substantially co-planar). Stated somewhat differently, the first and second electrically conductive structures 906, 908 are disposed over the same side of dielectric layer 903, with one or more dielectric vias 909, 910 disposed therebetween.

Like representative embodiments described more fully above, the representative embodiments of FIGS. 9A-9D have one or more dielectric vias 909, 910 disposed in regions of selected first-fourth dielectric layers 901-904 where the magnitude of the electric fields emanating between the first and second electrically conductive structures 906, 908, respectively, are comparatively large. Thereby, the parasitic capacitance between the first and second electrically conductive structures 906, 908 is reduced compared to a structure that does not comprise the dielectric vias 909, 910 of the representative embodiment. As noted above, unmitigated parasitic capacitance results in an undesired reduction in the characteristic impedance and/or an undesired reduction in the inductance of an electronic component (e.g., transmission line or inductor).

Stated somewhat differently, in regions where the magnitude of the electric field is comparatively high, the dielectric vias 909, 910, which have a low relative permittivity (∈ᵣ₂) compared to the relative permittivity of the selected first-fourth dielectric layers 901-904 provide a reduced relative effective permittivity ∈_{r,eff}, and therefore a reduction of the capacitive parasitics.

Turning to FIG. 9A, dielectric via 909 is disposed in the second and third dielectric layers 902, 903, and between the first and second electrically conductive structures 906, 908. Notably, the dielectric via 909 in each of the intervening dielectric layers 902, 903 is not necessarily completely or even partially aligned. Rather dielectric via 909 can be provided in dielectric layer 903 that is misaligned with respect to the dielectric via in dielectric layer 902. Beneficially, the dielectric via 909 disposed between the first and second electrically conductive structures 906, 908 reduces the relative effective permittivity ∈_{r,eff} therebetween.

Turning to FIG. 9B, dielectric via 909 is disposed in the first, second and third dielectric layers 901, 902, 903, and between the first and second electrically conductive structures 906, 908. Notably, the dielectric via 909 in each of the intervening dielectric layers 901, 902, 903 is not necessarily completely or even partially aligned. Rather dielectric via 909 can be provided in dielectric layer 903, that is misaligned with respect to the dielectric via in dielectric layer 902 or dielectric layer 901, or both. Beneficially, the dielectric via 909 disposed between a portion of the first and second electrically conductive structures 906, 908 in greater volume than in the embodiment of FIG. 9A further reduces the relative effective permittivity ∈_{r,eff} therebetween.

Turning to FIG. 9C, dielectric vias 909, 910 are disposed in the second and third dielectric layers 902, 903, and between the first and second electrically conductive structures 906, 908. Notably, the dielectric vias 909, 910 in each of the intervening dielectric layers 902, 903 are not necessarily completely or even partially aligned. Rather dielectric via 909 can be provided in dielectric layer 903, that is misaligned with respect to the dielectric via in dielectric layer 902. Beneficially, the dielectric vias 909, 910 disposed between the first and second electrically conductive structures 906, 908 in greater volume than in the embodiment of FIG. 9A further reduces the relative effective permittivity ∈_{r,eff} therebetween.

Turning to FIG. 9D, dielectric via 909 is disposed in the second and third dielectric layers 902, 903, and substantially fills these dielectric layers in the region between the first and second electrically conductive structures 906, 908. Beneficially, the dielectric via 909 disposed between the first and second electrically conductive structures 906, 908 in greater volume than in the embodiment of FIGS. 9A-9C further reduces the relative effective permittivity ∈_{r,eff} therebetween.

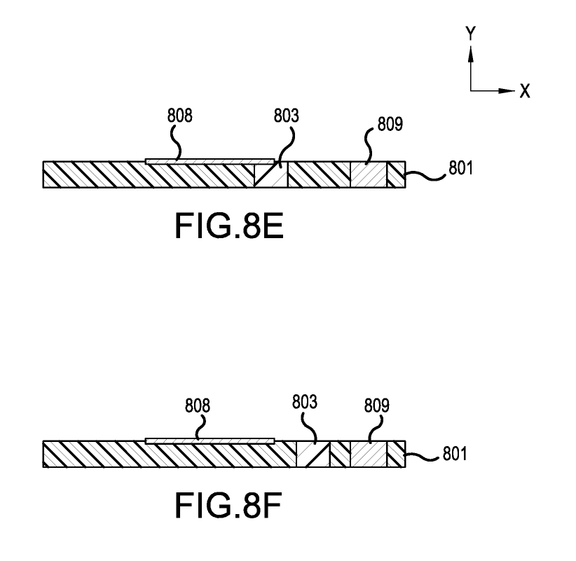

FIGS. 10-12 are cross-sectional views of various layers of apparatuses according to representative embodiments. Notably, many details of the various features described in connection with the representative embodiments of FIGS. 1A-1B, FIGS. 2A-2B, FIGS. 3A-3B, FIGS. 4A-4B, FIGS. 5A-5B, FIGS. 6A-6F, FIGS. 7A-7G, FIGS. 8A-8D, and FIGS. 10A-1D are common to those of the representative embodiments of FIGS. 10-12. These details are not necessarily repeated in the description of FIGS. 10-12.

Notably, each of FIGS. 10-12 depicts an apparatus comprising a multi-layer structure comprising a plurality of dielectric layers with various arrangements of electrically conductive structures one or more dielectric vias disposed in two or more of the dielectric layers. As in other representative embodiments described herein, the electrically conductive structures may be one of a variety of electrical components, including, but not limited to inductors, transmission lines, or delay lines, as well as reference ground planes and shielding layers. In yet other embodiments described herein, the electrically conductive structures may be impedance transformers.

The various arrangements depicted in FIGS. 10-12 are contemplated for use in apparatuses, such as those described above, and further herein. Stated somewhat differently, the various representative embodiments of FIGS. 10-12 are contemplated to be a multi-layer substrate used in an electronic module or similar structure, by way of example. It is emphasized that this contemplated implementation of the various embodiments of FIGS. 10-12 is merely illustrative, and other implementations are contemplated.

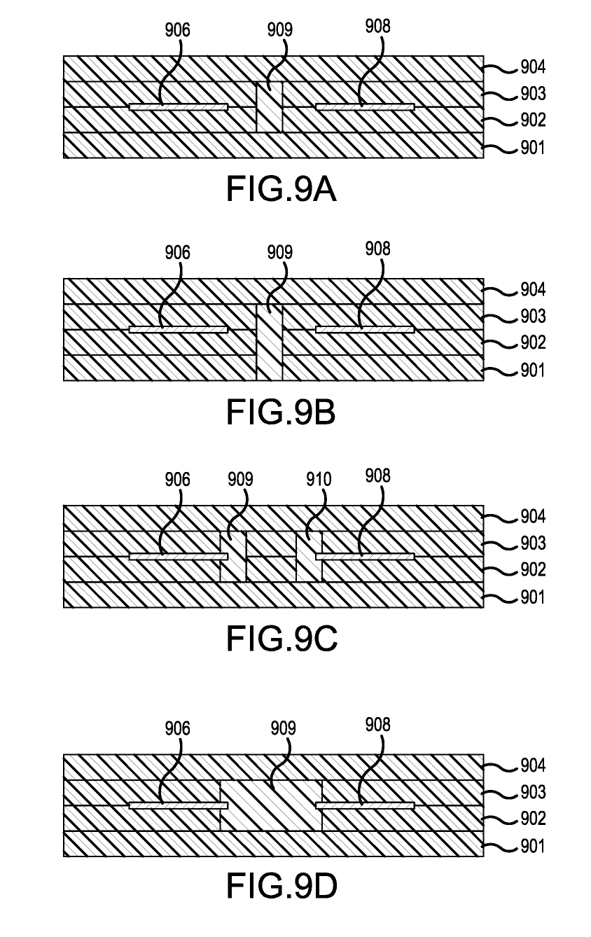

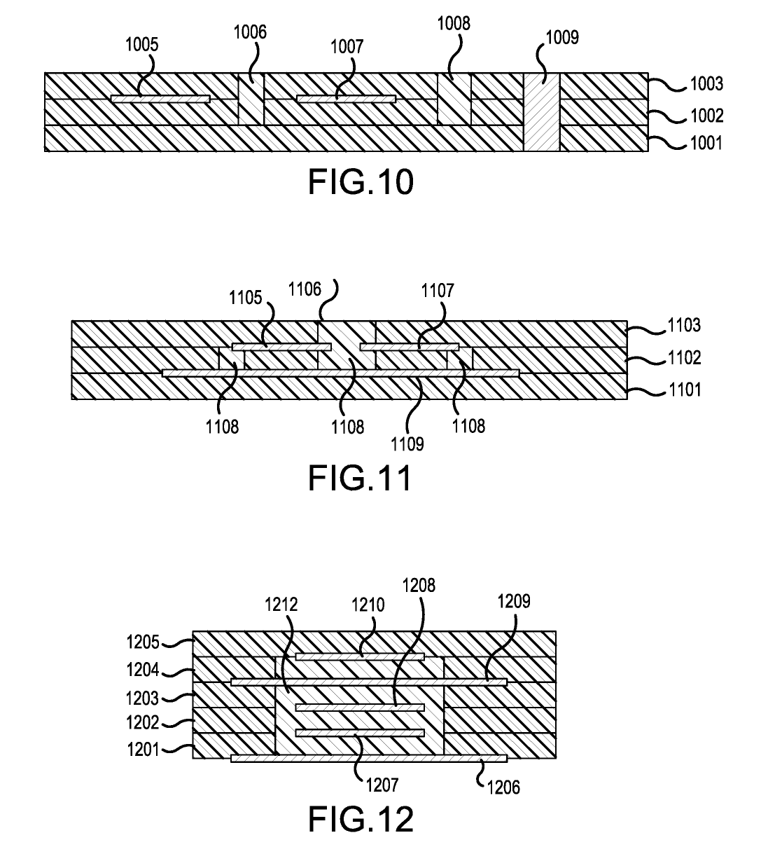

Generally, in the representative embodiments of FIG. 11, the electrically conductive structures are provided both vertical and horizontal arrangements, while the representative embodiment of FIG. 10 is in a horizontal arrangement and the representative embodiment of FIG. 12 is in a vertical arrangement.

Like representative embodiments described more fully above, the representative embodiments of FIGS. 10-12 have one or more dielectric vias disposed in regions of selected dielectric layers where the magnitude of the electric fields emanating between the electrically conductive structures are comparatively large. Thereby, the parasitic capacitance between the electrically conductive structures is reduced compared to a structure that does not comprise the dielectric vias of the representative embodiments. As noted above, unmitigated parasitic capacitance results in an undesired reduction in the characteristic impedance and/or an undesired reduction in the inductance of an electronic component (e.g., transmission line or inductor).

Turning to FIG. 10, an apparatus comprises first˜third dielectric layers 1001, 1002, 1003, first and second electrically conductive structures 1005, 1007, first and second dielectric vias 1006, 1008, and an electrically conductive via 1009.

First dielectric via 1006 is disposed between the first and second electrically conductive structures 1005, 1007 and in the second and third dielectric layers 1002, 1003. Second dielectric via 1008 is disposed between the second electrically conductive structure 1007 and the electrically conductive via 1009, which extends through first˜third dielectric layers 1001, 1002, 1003, and may be a reference ground. Beneficially, first and second dielectric vias 1006, 1008 disposed between the first and second electrically conductive structures 1005, 1007, and between the second electrically conductive structure 1007 and the electrically conductive via 1009 serves to reduce the relative effective permittivity ∈_{r,eff} in regions where the electric fields can be greater.

Turning to FIG. 11, an apparatus comprises first˜third dielectric layers 1101, 1102, 1103, first˜third electrically conductive structures 1105, 1107, 1109, and dielectric vias 1108.

One of the dielectric vias 1108 is disposed between the first and second electrically conductive structures 1105, 1107, and in the second and third dielectric layers 1102, 1103. This dielectric via 1108 is also disposed along respective ends of the first and second electrically conductive structures 1105, 1107, which overhang the dielectric via 1108. This dielectric via 1108 is thus disposed between the first and second electrically conductive structures 1105, 1107, and the third electrically conductive structure 1109. Notably, dielectric via 1108 in each of the intervening dielectric layers 1102, 1103 is not necessarily completely or even partially aligned. Rather, dielectric via 1108 may be provided in dielectric layer 1102, and may be misaligned with respect to the dielectric via in dielectric layer 1103.

The remaining two dielectric vias 1108 are disposed in the second dielectric layer 1102. These two dielectric vias 1108 are disposed between the first and second electrically conductive structures and the third electrically conductive structure 1109 at respective ends opposing the ends that extend over the other dielectric via 1108 disposed in the second and third dielectric layers 1102, 1103. The electrically conductive structure 1009, disposed between the first and second dielectric layer 1101, 1102, may be a reference ground. Beneficially, dielectric vias 1108 serve to reduce the relative effective permittivity ∈_{r,eff} in regions where the electric fields can be greater.

Turning to FIG. 12, an apparatus comprises first˜fifth dielectric layers 1201˜1205, first˜fifth electrically conductive structures 1206˜1210, and dielectric vias 1212. The first and fourth electrically conductive structures 1206, 1209 are illustratively maintained at a reference ground potential. The second and third electrically conductive structures 1207, 1208 are illustratively turns of an inductor, and the fifth electrically conductive structure 1210 is illustratively an inductor.

Beneficially, dielectric via 1212 serves to reduce the relative effective permittivity ∈_{r,eff} in regions where the electric fields can be greater.

In the representative embodiments described above, the dielectric vias each have a relative permittivity (∈ᵣ) that is less than the relative permittivity of the dielectric layer in which they are disposed. However, the present teachings contemplate an apparatus comprising a dielectric layer has a first relative permittivity (∈ᵣ₁), and a dielectric via disposed in the dielectric layer, wherein the dielectric via has a second relative permittivity (∈ᵣ₂) that is greater than the first relative permittivity (∈ᵣ₁). The dielectric via is located in a region, or adjacent to the region, where an electric field between the first and second electrically conductive structures exists.

By way of example and not limitation, the structure from FIG. 6F is as described above except the permittivity (∈ᵣ₂) of the dielectric via 602 is greater than the relative permittivity (∈ᵣ₁) of the dielectric layer 601. By providing the dielectric via 602 in regions where the electric field exists between the second electrically conductive structure 604 and the first electrically conductive structure 603, the capacitance between the second electrically conductive structure 604 and the first electrically conductive structure 603 is increased compared to a structure that does not comprise the dielectric vias 602 of the representative embodiment. Stated somewhat differently, the relative effective permittivity ∈_{r,eff} is increased due to the partial located dielectric vias 602, which have a high relative permittivity (∈ᵣ₂) compared to the relative permittivity of the dielectric layer 601.

This increased relative effective permittivity ∈_{r,eff} is useful in applications of signal transmission lines or delay lines (e.g. microstip, stripline), because the electrical line-length is directly proportional to the wavelength and the wavelength is inversely proportional to the root of the relative effective permittivity ∈_{r,eff}. Consequently, for example, when the first electrically conductive structure 603 is a reference ground and the second electrically conductive structure 604 is a delay line, the line-length can be shortened by placing one or more dielectric vias 602 between both electrically conductive structures 603, 604.

Notably, by placing dielectric vias partial between the transmission line/delay line (first electrically conductive structure 603) and its reference ground (second electrically conductive structure 604) the relative effective permittivity ∈_{r,eff} will be decrease when ∈ᵣ₂ is less than ∈ᵣ₁ and increase when ∈ᵣ₂ is greater than ∈ᵣ₁. As will be appreciated, the in transmission line applications, the ability to provide and increased or decreased relative effective permittivity ∈_{r,eff} allows for design flexibility as needed. In contrast to transmission lines, inductors will benefit from a low relative effective permittivity ∈_{r,eff} only which will decrease the capacitive parasitics as described above.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. An apparatus, comprising:
a first electrically conductive structure at first electrical potential;
a second electrically conductive structure at a second electrical potential;
a dielectric layer disposed between the first electrically conductive structure and the second electrically conductive structure, the dielectric layer having a first relative permittivity (∈ᵣ₁); and
a dielectric via disposed in the dielectric layer, the dielectric via having a second relative permittivity (∈ᵣ₂) that is less than the first relative permittivity (∈ᵣ₁), the dielectric via being located in a region, or adjacent to the region, where a magnitude of an electric field between the first and second electrically conductive structures is comparatively large.

2. The apparatus of claim 1, wherein the dielectric layer has a first side and a second side, and the first and second electrically conductive structures are on the same one of the first and second sides.

3. The apparatus of claim 1, wherein the dielectric layer has a first side and a second side, and the first and second electrically conductive structures are on opposing sides of the first and second sides.

4. The apparatus of claim 1, wherein the lateral dimension of the dielectric via is comparatively small in relation to the first and second electrically conductive structures.

5. The apparatus of claim 1, wherein the dielectric via comprises air.

6. The apparatus of claim 1, wherein the dielectric via comprises a low-k dielectric material.

7. The apparatus of claim 1, wherein the dielectric via extends from one side of the dielectric layer through to an opposing side of the dielectric layer, the dielectric via having sidewalls that do not comprise an electrically conductive material.

8. The apparatus of claim 1, further comprising:
at least one additional dielectric via disposed in the dielectric layer, the dielectric via having the second relative permittivity (∈ᵣ₂), or a third relative permittivity (∈ᵣ₃) that is less than the first relative permittivity (∈ᵣ₁), wherein the at least one additional dielectric via is located in a region, or adjacent to the region where the magnitude of an electric field between the first and second electrically conductive structures is comparatively large.

9. The apparatus of claim 1, wherein the first electrically conductive structure comprises an inductor, and the second electrically conductive structure is a shield metallization.

10. The apparatus of claim 1, wherein the first electrically conductive structure comprises a first inductor, and the second electrically conductive structure comprises a second inductor.

11. The apparatus of claim 1, wherein first electrically conductive structure is a first turn of an inductor, and the second electrically conductive structure is a second turn of the inductor.

12. The apparatus of claim 1, wherein the first electrically conductive structure is a signal transmission line, and the second electrically conductive layer is a reference ground or at least a part of a reference ground plane.

13. The apparatus of claim 1, wherein the first electrically conductive structure is a signal transmission line, and the second electrically structure is a shield metallization.

14. The apparatus of claim 1, wherein the first electrically conductive structure comprises an inductor and the second electrically structure is an electrically conductive via.

15. The apparatus of claim 1, wherein the first electrically conductive structure comprises a signal transmission line, and the second electrically structure comprises an electrically conductive via.

16. The apparatus of claim 1, wherein the dielectric layer comprises a plurality of dielectric layers.

17. The apparatus of claim 16, wherein at least one additional dielectric via disposed in one of the dielectric layers, the dielectric via having the second relative permittivity (∈ᵣ₂), or a third relative permittivity (∈₃) that is less than the first relative permittivity (∈ᵣ₁), wherein the at least one additional dielectric via is located where the magnitude of an electric field between the first and second electrically conductive layers is comparatively large.

18. The apparatus of claim 17, wherein the dielectric layers are components of an RF module.

19. The apparatus of claim 18, wherein the RF module comprises an acoustic filter, or an amplifier, or both.

20. The apparatus of claim 19, wherein the acoustic filter comprises bulk acoustic wave (BAW) resonators.

21. The apparatus of claim 20, wherein the BAW resonators comprise thin film bulk acoustic resonators (FBARs).

22. The apparatus of claim 19, wherein the acoustic filter comprises surface acoustic wave (SAW) resonators.

23. An apparatus, comprising:
a first electrically conductive structure at first electrical potential;
a second electrically conductive structure at a second electrical potential;
a dielectric layer disposed between the first electrically conductive structure and the second electrically conductive structure; and
a dielectric via disposed in the dielectric layer, the dielectric via being located in a region, or adjacent to the region, where a magnitude of an electric field between the first and second electrically conductive structures is comparatively large, wherein an relative permittivity of the dielectric layer is macroscopically altered by the dielectric via disposed in the dielectric layer relative to a substrate not comprising the dielectric via.

24. The apparatus of claim 23, further comprising at least one additional dielectric via.

25. The apparatus of claim 24, wherein the dielectric via has a relative permittivity of that is less than a relative permittivity of the dielectric layer, and the macroscopic relative permittivity of the dielectric layer is less than the substrate not comprising the dielectric via.

26. The apparatus of claim 24, wherein the dielectric via has a relative permittivity of that is greater than a relative permittivity of the dielectric layer, and the macroscopic relative permittivity of the dielectric layer is greater than the substrate not comprising the dielectric via.

27. The apparatus of claim 24, wherein the first electrical conductive structure comprises a transmission line, and the second conductive structure is connected to a reference ground.

28. The apparatus of claim 27, wherein the relative permittivity of the dielectric via is less than the relative permittivity of the dielectric layer to achieve a higher characteristic impedance of the transmission line.

29. The apparatus of claim 27, wherein the relative permittivity of the dielectric via is greater than the relative permittivity of the dielectric layer to achieve a lower characteristic impedance of the transmission line.

30. The apparatus of claim 27, wherein the relative permittivity of the dielectric via is greater than the relative permittivity of the dielectric layer to increase an electrical delay of the transmission line.

31. The apparatus of claim 23, wherein the dielectric layer comprises a plurality of dielectric layers.

32. The apparatus of claim 31, wherein the dielectric layers are components of an RF module.

33. The apparatus of claim 32, wherein the RF module comprises an acoustic filter, or an amplifier, or both.

34. The apparatus of claim 33, wherein the acoustic filter comprises bulk acoustic wave (BAW) resonators.

35. The apparatus of claim 34, wherein the BAW resonators comprise thin film bulk acoustic resonators (FBARs).

36. The apparatus of claim 33, wherein the acoustic filter comprises surface acoustic wave (SAW) resonators.

37. The apparatus of claim 23, wherein the first electrically conductive structure comprises a inductor and the second electrically conductive structure is connected to a reference ground, the relative permittivity of the dielectric via being less than the relative permittivity of the dielectric layer to achieve a higher self-resonance frequency of the inductor.

38. An apparatus, comprising:
a first electrically conductive structure at first electrical potential;
a second electrically conductive structure at a second electrical potential;
a dielectric layer disposed between the first electrically conductive structure and the second electrically conductive structure, the dielectric layer having a first relative permittivity (∈ᵣ₁); and
a dielectric via disposed in the dielectric layer, the dielectric via having a second relative permittivity (∈ᵣ₂) that is greater than the first relative permittivity (∈ᵣ₁), the dielectric via being located in a region, or adjacent to the region, wherein an electric field exists between the first and second electrically conductive structures.

39. The apparatus of claim 38, wherein the dielectric layer has a first side and a second side, and the first and second electrically conductive structures are on the same one of the first and second sides.

40. The apparatus of claim 38, wherein the dielectric layer has a first side and a second side, and the first and second electrically conductive structures are on opposing sides of the first and second sides.

41. The apparatus of claim 38, wherein the lateral dimension of the dielectric via is comparatively small in relation to the first and second electrically conductive structures.

42. The apparatus of claim 38, wherein the dielectric via extends from one side of the dielectric layer through to an opposing side of the dielectric layer, the dielectric via having sidewalls that do not comprise an electrically conductive material.

43. The apparatus of claim 38, further comprising:
at least one additional dielectric via disposed in the dielectric layer, the dielectric via having the second relative permittivity (∈ᵣ₂), or a third relative permittivity (∈ᵣ₃) that is greater than the first relative permittivity (∈ᵣ₁), wherein the at least one additional dielectric via is located in a region, or adjacent to the region where the electric field exists between the first and second electrically conductive structures is comparatively large.

44. The apparatus of claim 38, wherein the first electrically conductive structure comprises an transmission line or a delay line, and the second electrically conductive structure is a shield metallization.
